(19) United States
(12) Patent Application Publication
(10) Pub. No.: US 2013/0069101 A1
(43) Pub. Date: Mar. 21, 2013

(54) METHOD FOR MANUFACTURING LED AND LED OBTAINED THEREBY

(71) Applicants: HSIN-CHIANG LIN, Hukou (TW); WEN-LIANG TSENG, Hukou (TW); LI-HSIANG CHEN, Hukou (TW); HSING-FEN LO, Hukou (TW)

(72) Inventors: HSIN-CHIANG LIN, Hukou (TW); WEN-LIANG TSENG, Hukou (TW); LI-HSIANG CHEN, Hukou (TW); HSING-FEN LO, Hukou (TW)

(73) Assignee: ADVANCED OPTOELECTRONIC TECHNOLOGY, INC., Hsinchu Hsien (TW)

(21) Appl. No.: 13/569,120

(22) Filed: Aug. 7, 2012

(30) Foreign Application Priority Data
Sep. 16, 2011 (CN) 201110275572.7

(51) Int. Cl. H01L 33/52

(52) U.S. Cl. 257/99; 438/26; 257/E33.059

(57) ABSTRACT

A method for manufacturing a light emitting diode is disclosed. Firstly, two leads each including a plateau are provided. A blocking layer is then formed on each plateau. A base is molded on the leads to embed the two leads therein, wherein the two blocking layer are exposed from the base. The blocking layers are removed from the plateaus so that the two plateaus are exposed. A light emitting chip is bonded on one plateau with a wire connecting the chip with the other plateau. Finally, an encapsulant is formed on the base to seal the chip and the wire.

### BACKGROUND

1. Technical Field

The present disclosure relates to methods for manufacturing light emitting devices, and more particularly, to a method for manufacturing an LED (light emitting diode) and an LED obtained by the method.

2. Description of Related Art

As a new type of light source, LEDs are widely used in various applications. An LED often includes a base, a pair of leads formed in the base, a light emitting chip mounted on the base and electrically connected to the leads, and an encapsulant sealing the chip. Generally, each lead is embedded in the base with a top end exposed on a top face of the base and a bottom end exposed on a bottom surface of the base. The top end of each lead has an exposed top surface electrically connected to the chip through wires or other methods, and the bottom end of each lead has an exposed bottom surface electrically connected to external electrical structures such as a printed circuit board.

The base is typically molded on the leads by injection molding. However, during the injection molding, burrs may be formed on the exposed top surfaces of the top ends of the leads due to an engagement between the mold for the injection molding and the exposed top surfaces of the top ends of the leads. Such burrs will affect normal electrical contact between the top ends of the leads and the wires, thereby jeopardizing the quality of the LED. Furthermore, the top ends of the leads are all flat with bottom faces thereof engaging with the base only. Such engagement sometimes is insufficient to hold the leads to the base, whereby the top ends of leads may warp after a period of use due to internal stress and separate from the base. This also will affect the quality of the LED.

What is needed, therefore, is a method for manufacturing an LED and an LED obtained thereby which can overcome the limitations described above.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 shows a first step of a method for manufacturing an LED in accordance with an embodiment of the present disclosure.

FIG. 2 shows a second step of the method for manufacturing the LED in accordance with the embodiment of the present disclosure.

FIG. 3 shows a third step of the method for manufacturing the LED in accordance with the embodiment of the present disclosure.

FIG. 4 shows a fourth step of the method for manufacturing the LED in accordance with the embodiment of the present disclosure.

FIG. 5 shows a fifth step of the method for manufacturing the LED in accordance with the embodiment of the present disclosure.

FIG. 6 shows a sixth step of the method for manufacturing the LED in accordance with the embodiment of the present disclosure.

FIG. 7 shows a top view of FIG. 6.

FIG. 8 shows a seventh step of the method for manufacturing the LED in accordance with the embodiment of the present disclosure.

FIG. 9 shows the LED obtained by the present disclosure, which has been manufactured after the steps of FIGS. 1-8.

### DETAILED DESCRIPTION OF THE EMBODIMENTS

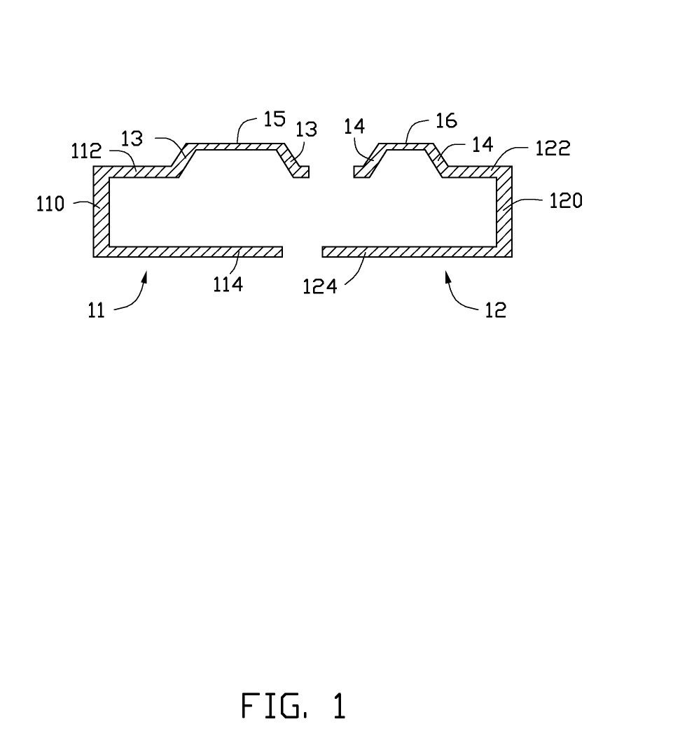

Referring to FIGS. 1-9, a method for manufacturing an LED 100 in accordance with an embodiment of the present disclosure is shown. The method mainly includes several steps as discussed below.

Firstly, two leads 11, 12 are provided as shown in FIG. 1. The two leads 11, 12 are separated from each other. Each of the two leads 11, 12 includes a bottom section 114, 124, a top section 112, 122 above the bottom section 114, 124 and a middle section 110, 120 interconnecting the bottom section 114, 124 and the top section 112, 122. The top section 112, 122 of each lead 11, 12 is stamped to have a plateau 15, 16 protruding upwardly and two inclined portions 13, 14 connected to two opposite ends of the plateau 15, 16. The plateau 15, 16 is parallel to the bottom section 114, 124 and perpendicular to the middle section 110, 120. The plateau 16 of the top section 122 of a right lead 12 has a size smaller than the plateau 15 of the top section 112 of a left lead 11.

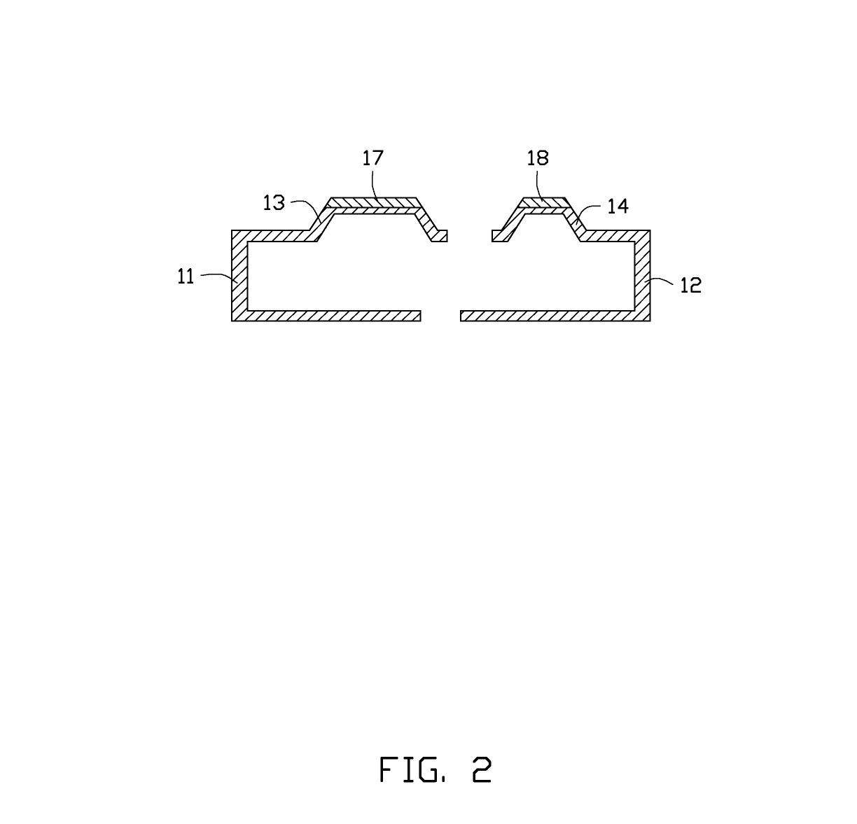

As shown in FIG. 2, two blocking layers 17, 18 are formed on the two plateaus 15, 16 of the two leads 11, 12, respectively. The two blocking layers 17, 18 may be made of photoresist or polymer compound materials. Each blocking layer 17, 18 wholly covers a top face of the plateau 15, 16 of a corresponding top section 112, 122. The other parts of the corresponding top section 112, 122 are exposed outside each blocking layer 17, 18. Each blocking layer 17, 18 has two inclined sides coincidental with the two inclined portions 13, 14 of the corresponding top section 112, 122.

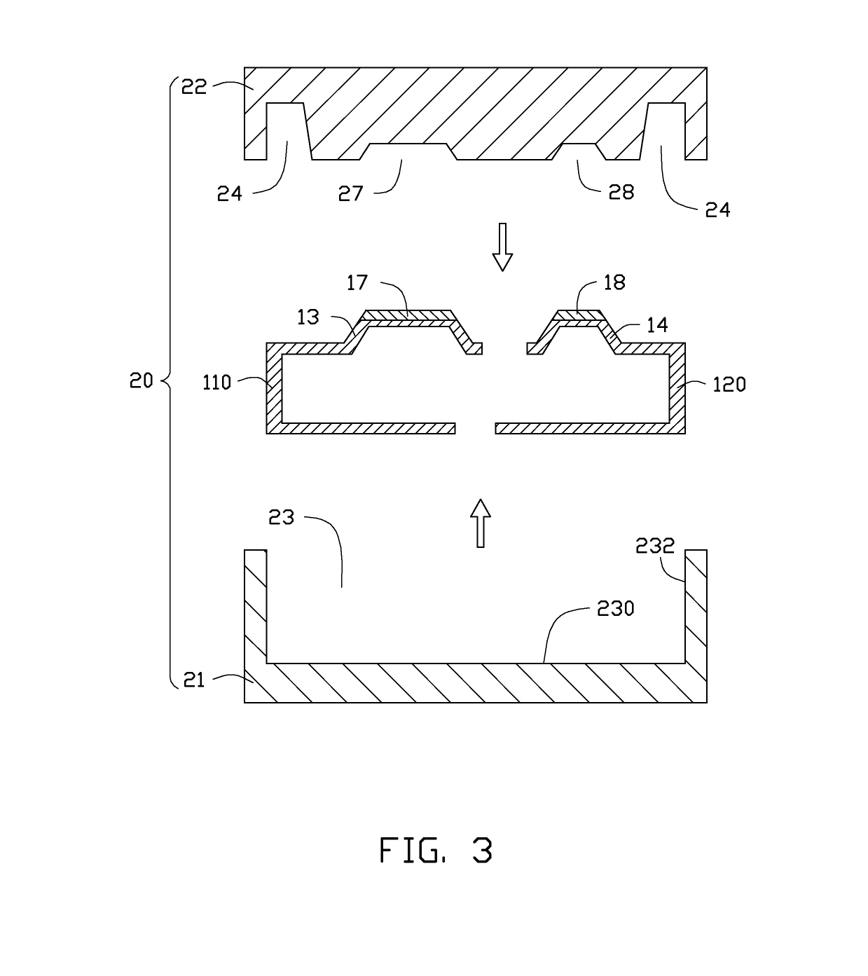

As shown in FIG. 3, a mold unit 20 is provided. The mold unit 20 includes a first mold 22 and a second mold 21 separated from the first mold 22. The first mold 22 is located above the two leads 11, 12, and the second mold 21 is located below the two leads 11, 12. The first mold 22 defines an annular groove 24 and two recesses 27, 28 in a bottom face thereof. The two recesses 27, 28 are surrounded by the annular groove 24. The two recesses 27, 28 are located corresponding to the two plateaus 15, 16 of the two leads 11, 12, and the annular groove 24 is located generally corresponding to the two middle sections 110, 120 of the two leads 11, 12. Each recess 27, 28 has a depth larger than a thickness of a corresponding blocking layer 17, 18, and the annular groove 24 has a depth larger than that of the two recesses 27, 28. The second mold 21 defines a large chamber 23 in a top face thereof. The chamber 23 has a depth equal to a height of each lead 11, 12 so that the two leads 11, 12 can be substantially totally received in the chamber 23. The second mold 21 has a horizontal inner face 230 defining a bottom of the chamber 23 and a plurality of vertical inner faces 232 defining laterals of the chamber 23.

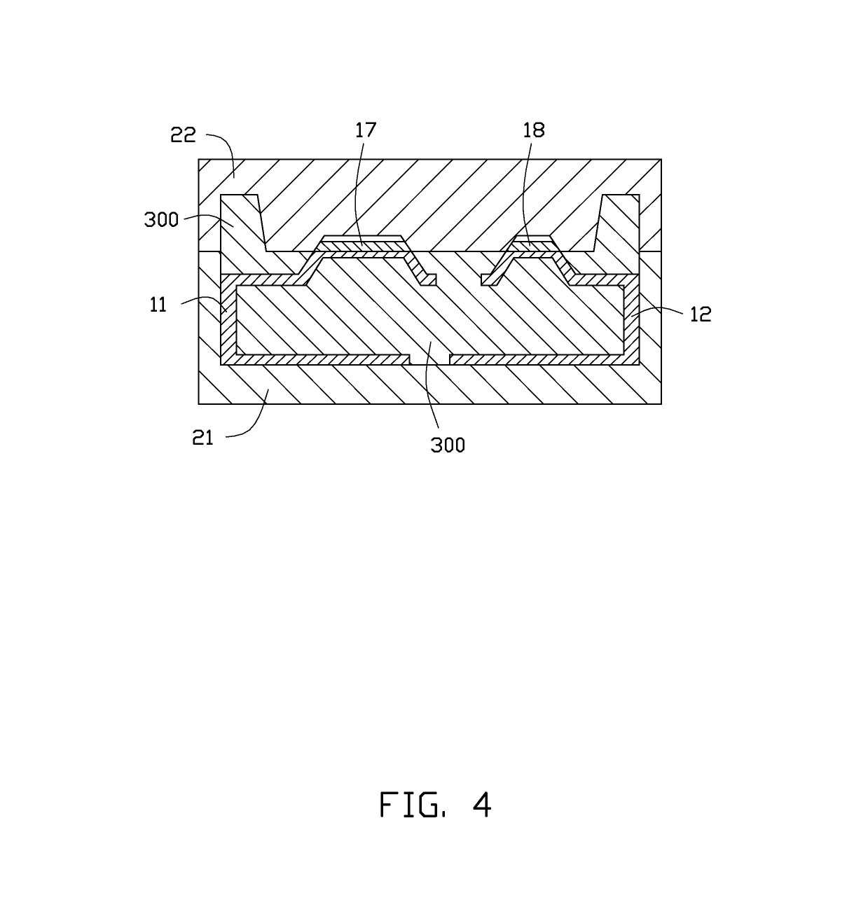

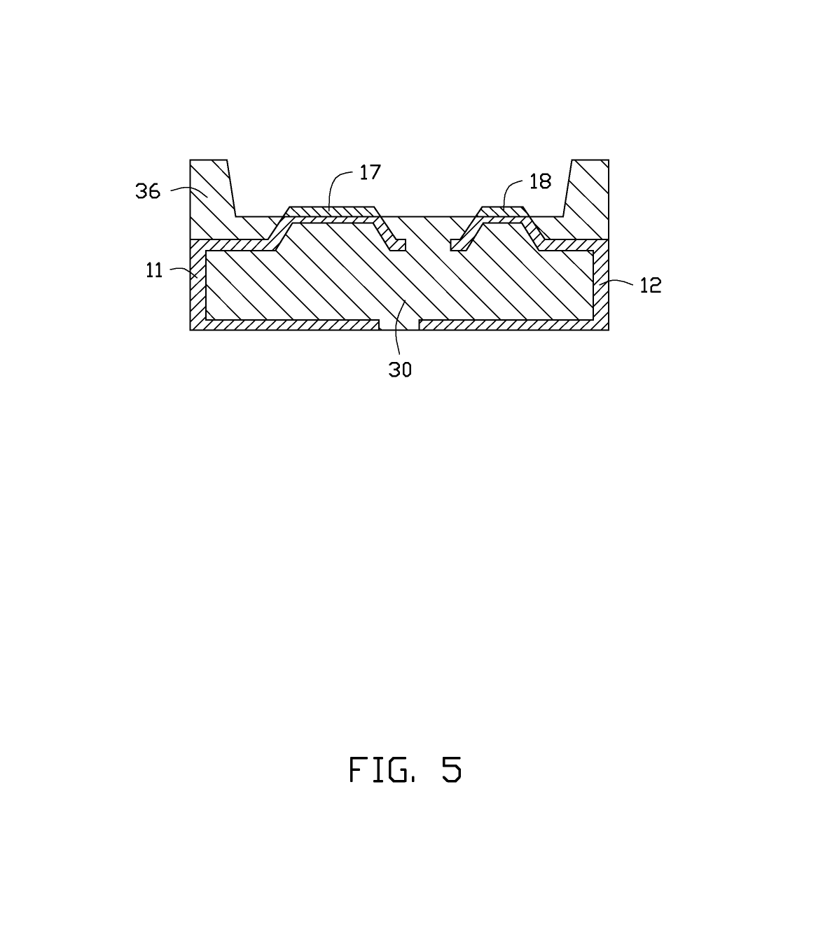

As shown in FIG. 4, the first mold 22 and the second mold 21 are brought to move towards each other until the first mold 22 and the second mold 21 join together. The two leads 11, 12 are completely received in the chamber 23 of the second mold 21, and the two blocking layers 17, 18 are totally received in the two recesses 27, 28, respectively. The bottom sections 114, 124 of the two leads 11, 12 abut against the horizontal inner face 230 of the second mold 21, and the middle sections 110, 120 of the two leads 11, 12 abut against the vertical inner faces 232 of the second mold 21. A molding material 300 is injected into the chamber 23. The molding material 300 fills the chamber 23 and the annular groove 24. The two recesses 27, 28 are blocked by the two blocking layers 17, 18 so that no molding material 300 enters the two recesses 27, 28. The molding material 300 engages an entirety of the top sections 112, 122 of the leads 11, 12, except the top surfaces of the plateaus 15, 16, which are covered by the blocking layers 17, 18. The molding material 300 is then cured to harden to form a base 30 (see FIG. 5). The molding material 300 filling the annular groove 24 forms an annular sidewall 36 (see FIG. 5) on a top face of the base 30. The annular sidewall 36 surrounds the two blocking layers 17, 18. The annular sidewall 36 forms a reflective cup for the LED 100. Reflective material such a silver film can be coated on an inner surface of the annular sidewall 36.

The first mold 22 and the second mold 21 are removed from the two leads 11, 12 as shown in FIG. 5. The two blocking layers 17, 18 are exposed out of the base 30.

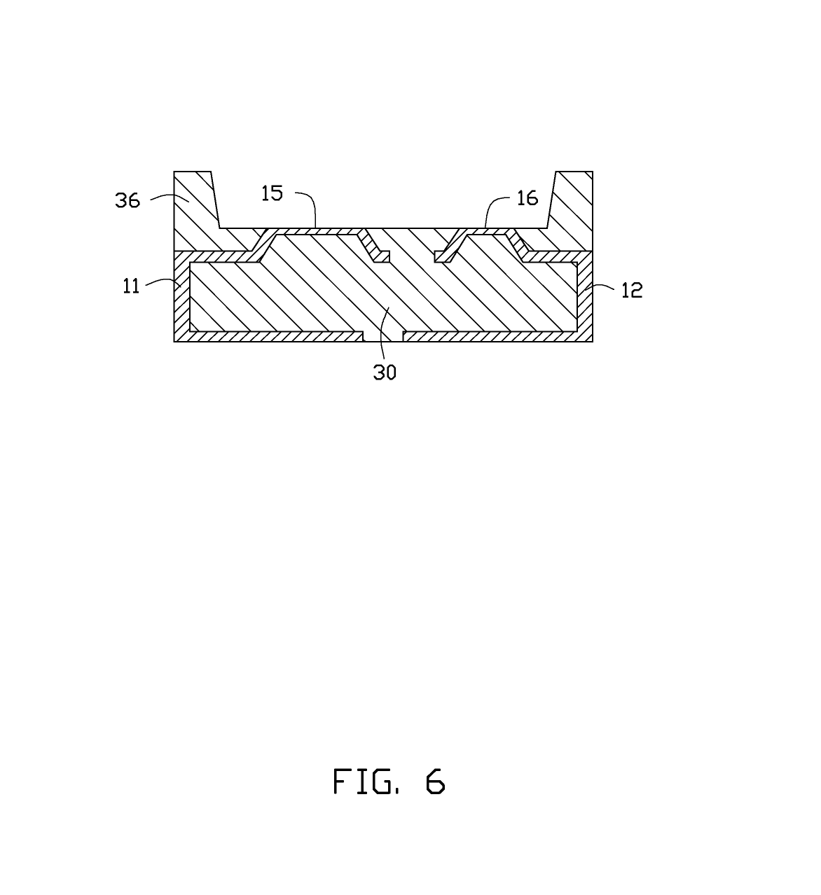

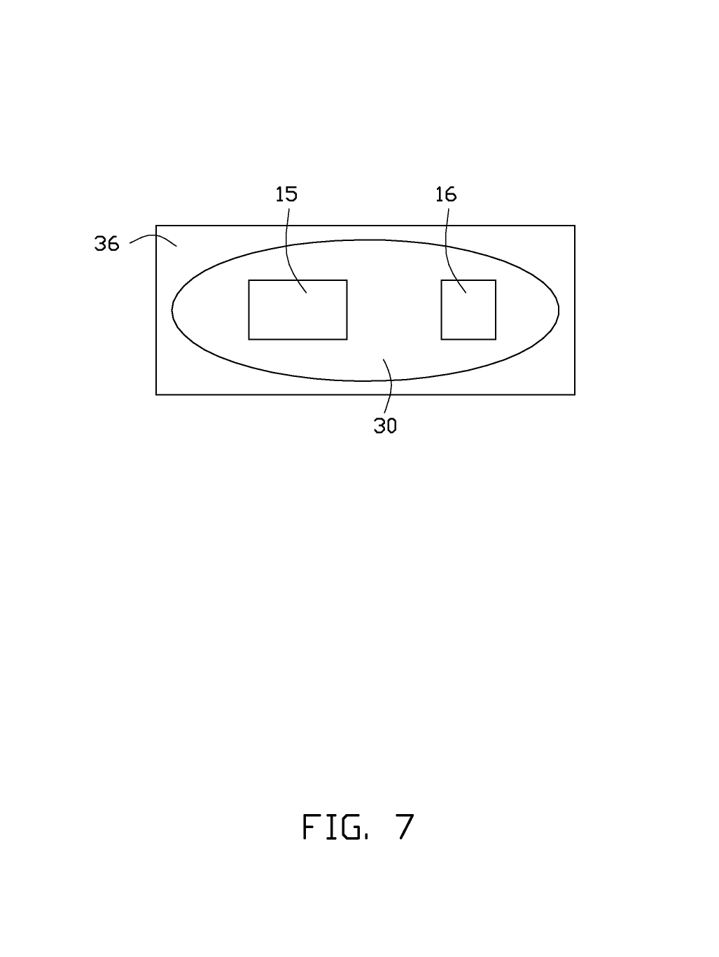

As shown in FIGS. 6-7, the two blocking layers 17, 18 are then removed from the two plateaus 15, 16 via etching, radiation or other suitable methods. The two plateaus 15, 16 are thus exposed from the base 30. Since the top faces of the two plateaus 15, 16 are covered by the two blocking layers 17, 18 during injection of the molding material 300 and do not have any engagement with the mold unit 20, burr cannot formed on the top faces of the two plateaus 15, 16. Thus, the top faces of the two plateaus 15, 16 can keep intact after removing the two blocking layers 17, 18.

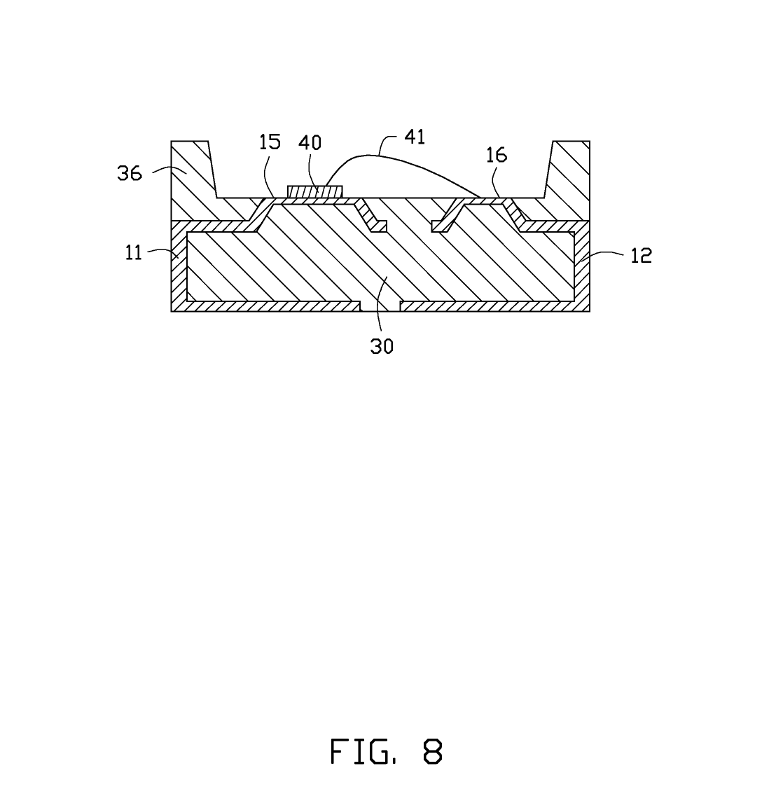

A light emitting chip 40 is attached on a larger plateau 15 as shown in FIG. 8. The attachment of the chip 40 to the top face of the larger plateau 15 may be achieved by electrically-conductive materials such as silver adhesive. The chip 40 is further electrically connected to a smaller plateau 16 through a wire 41. Since the top faces of the two plateaus 15, 16 are intact, the electrical connection between the chip 40 and the two plateaus 15, 16 can be optimal.

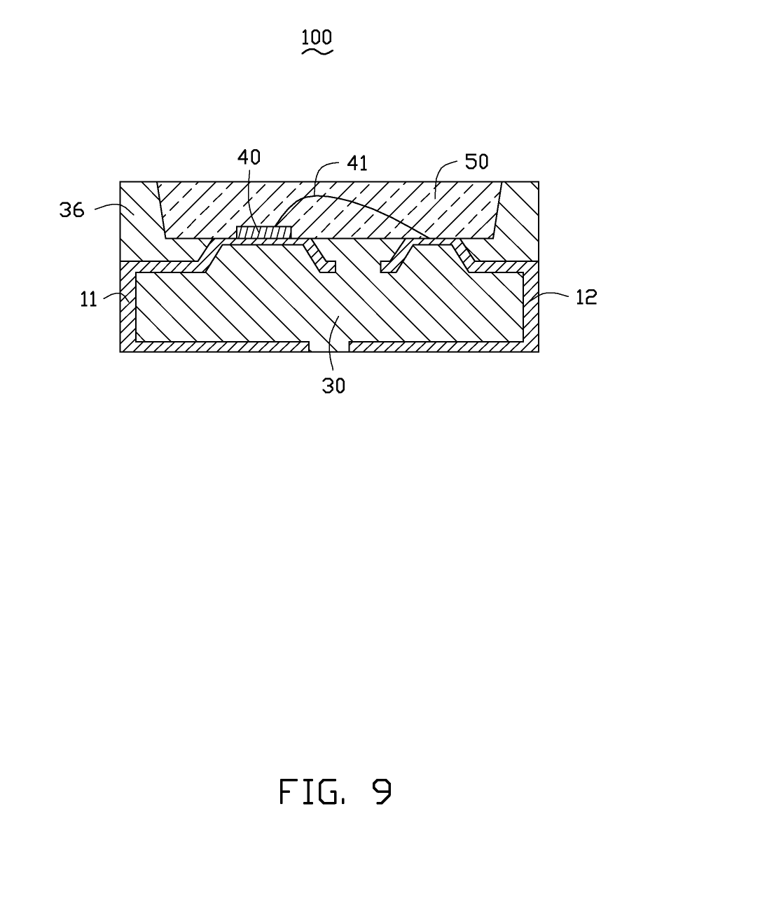

Finally, an encapsulant 50 is formed in the base 30 to be surrounded by the annual sidewall 36 and seal the chip 40 and the wire 41 as shown in FIG. 9. The encapsulant 50 is transparent so that light emitted from the chip 40 can pass through the encapsulant 50 to an outside environment. Phosphors (not shown) may be further doped within the encapsulant 50 to change color of the light emitted from the chip 40.

It is believed that the present disclosure and its advantages will be understood from the foregoing description, and it will be apparent that various changes may be made thereto without departing from the spirit and scope of the present disclosure or sacrificing all of its material advantages, the examples hereinbefore described merely being preferred or exemplary embodiments.

What is claimed is:

1. A method for manufacturing an LED (light emitting diode), comprising:
providing a pair of leads each comprising a plateau;
forming a blocking layer on each plateau;
forming a base joining the leads and avoiding the blocking layers so that the blocking layers are exposed outside the base;
removing the blocking layers to expose the plateaus;
electrically connecting a light emitting chip with the two plateaus; and
sealing the light emitting chip with an encapsulant.

2. The method of claim 1, wherein the plateau of the each lead is located higher than the other parts of each lead.

3. The method of claim 1, wherein each lead comprises a bottom section, a top section and a middle interconnecting the top section and the bottom section, the plateau being a part of the top section.

4. The method of claim 3, wherein the plateau is parallel to the bottom section and perpendicular to the middle section.

5. The method of claim 3, wherein the top section comprises two inclined portions connecting with the plateau thereof.

6. The method of claim 1, wherein the base is formed by putting the two leads between a first mold and a second mold and then filling a molding material between the first mold and the second mold to form the base.

7. The method of claim 6, wherein the first mold and the second mold are separable from each other.

8. The method of claim 6, wherein the second mold defines a chamber receiving the two leads, the two blocking layers being located above the chamber.

9. The method of claim 6, wherein the first mold defines two recesses receiving the two blocking layers, respectively.

10. The method of claim 9, wherein during filling the molding material, the two recesses are blocked by the two blocking layers whereby no molding material enters the two recesses.

11. The method of claim 6, wherein the first mold further defines an annular groove surrounding the two recesses.

12. The method of claim 11, wherein the molding material fills the annular groove to form an annular sidewall.

13. The method of claim 6, wherein the molding material is harden after filling the molding material between the first mold and the second mold, and the first mold and the second mold are then removed.

14. The method of claim 1, wherein the two plateaus have sizes different from each other.

15. The method of claim 14, wherein the light emitting chip is bonded on a larger one of the two plateaus, and a wire connects the light emitting chip with a smaller one of the two plateaus.

16. The method of claim 1, wherein the blocking layers are made of photoresist or polymer compound materials.

17. An LED (light emitting diode) comprising:
a base having a annular sidewall extending upwardly from a top face thereof;
a first lead having a bottom section attached to a bottom face of the base, an lateral section extending upwardly from an outer end of the bottom section and engaging a side face of the base and a top section extending inwardly from a top end of the lateral section, the top section having a plateau protruding upwardly and at least an inclined portion extending downwardly inclinedly from at least an end of the plateau, the base engaging an entirety of the top section except a top face of the plateau;
a second lead having a bottom section attached to the bottom face of the base, an lateral section extending upwardly from an outer end of the bottom section of the second lead and engaging the side face of the base and a top section extending inwardly from a top end of the lateral section of the second lead, the top section of the second lead having a plateau protruding upwardly and at least an inclined portion extending downwardly inclinedly from at least an end of the plateau of the top section of the second lead, the base engaging an entirety of the top section of the second lead except a top face of the plateau of the top section of the second lead;
an LED chip electrically connecting with the top faces of the plateaus of the top sections of the first and second leads; and
encapsulant in the base and surrounded by the annular sidewall, the encapsulant enclosing the LED chip therein.

18. The LED of claim 17, wherein the LED chip is mounted on the top face of the plateau of the top section of first lead and electrically connects with the top face of the plateau of the top section of the second lead by a conductive wire.

19. The LED of claim 18, wherein the annular sidewall and the base are integrally formed as a monolithic piece.

20. The LED of claim 18, wherein the LED chip is electrically connected to the top face of the plateau of the top section of the first lead by electrically conductive adhesive adhering the LED chip to the top face of the plateau of the top section of the first lead.
